(19) United States
(12) Patent Application Publication
(10) Pub. No.: US 2025/0301860 A1
(43) Pub. Date: Sep. 25, 2025

(54) ELECTRO-OPTICAL DEVICE AND ELECTRONIC APPARATUS

(71) Applicant: SEIKO EPSON CORPORATION, Tokyo (JP)

(72) Inventor: Yuiga HAMADE, Matsumoto-shi (JP)

(73) Assignee: SEIKO EPSON CORPORATION, Tokyo (JP)

(21) Appl. No.: 19/087,805

(22) Filed: Mar. 24, 2025

(30) Foreign Application Priority Data
Mar. 25, 2024 (JP) 2024-047710

(51) Int. Cl. H10K 59/122; H10K 59/131; H10K 59/80

(52) U.S. Cl. CPC H10K 59/122; H10K 59/131; H10K 59/805

(57) ABSTRACT

The electro-optical device includes a light-emitting element having a light-emitting layer sandwiched between a pixel electrode and a common electrode and being in contact with the light-emitting layer in an opening region of a pixel separation layer, a partition wall surrounding the light-emitting element and the common electrode in plan view, an insulating sealing layer having an insulating property and transparency and covering the light-emitting element and the partition wall, and a planarization layer having an insulating property and transparency, covering the sealing layer, and having a higher refractive index than the sealing layer, in which a surface facing the planarization layer of the sealing layer in the opening region in plan view is a concave surface in cross-sectional view.

The present application is based on, and claims priority from JP Application Serial Number 2024-047710, filed Mar. 25, 2024, the disclosure of which is hereby incorporated by reference herein in its entirety.

### BACKGROUND

### 1. Technical Field

The present disclosure relates to an electro-optical device and an electronic apparatus.

### 2. Related Art

As a light-emitting element, for example, an electro-optical device using an OLED is known. OLED is an abbreviation for Organic Light Emitting Diode. Such a light-emitting element has a configuration in which a light-emitting layer is sandwiched between a pixel electrode and a common electrode. A technology in which such an electro-optical device includes a substrate, a plurality of light-emitting elements provided on the substrate, a plurality of filters (colored layers) provided above the plurality of light-emitting elements, and a wall portion surrounding each of the colored layers in plan view, and each of the colored layers has a concave surface on the display surface side (see, for example, International Publication No. 2023/068227).

In recent years, in an electro-optical device with a small pixel size, it is desirable to increase the luminance in a front direction and the efficiency of light use to reduce power consumption and extend the life of a light-emitting layer.

### SUMMARY

In order to solve the above problem, an electro-optical device according to an aspect of the present disclosure includes a light-emitting element including a first electrode, a second electrode, and a light-emitting layer provided between the first electrode and the second electrode, a partition wall configured to surround the light-emitting element in plan view, a first insulating layer configured to cover the periphery of the first electrode and having an opening region overlapping the first electrode in plan view, a second insulating layer having an insulating property and transparency and configured to cover the light-emitting element and the partition wall, and a third insulating layer having an insulating property and transparency, configured to cover the second insulating layer, and having a higher refractive index than the second insulating layer, wherein the first electrode and the light-emitting layer are in contact with each other in the opening region, and a surface of the second insulating layer in the opening region facing the third insulating layer is a concave surface in plan view.

### BRIEF DESCRIPTION OF THE DRAWINGS

FIG. 1 is a perspective view illustrating a configuration of an electro-optical device according to a first embodiment.

FIG. 2 is a diagram illustrating an electrical configuration of the electro-optical device.

FIG. 3 is a diagram illustrating a configuration of a pixel circuit in the electro-optical device.

FIG. 4 is a diagram illustrating an operation of the electro-optical device.

FIG. 5 is a plan view illustrating main portions of a pixel portion in the electro-optical device.

FIG. 6 is a partial cross-sectional view schematically illustrating the electro-optical device.

FIG. 7 is a partial cross-sectional view illustrating the electro-optical device.

FIG. 8 is a partial cross-sectional view illustrating the electro-optical device.

FIG. 9 is a partial enlarged cross-sectional view illustrating the electro-optical device.

FIG. 10 is a partial enlarged cross-sectional view illustrating a path of emitted light from the electro-optical device.

FIG. 11 is a partial enlarged cross-sectional view illustrating an electro-optical device according to a second embodiment.

FIG. 12 is a partial enlarged cross-sectional view illustrating a path of emitted light from the electro-optical device.

FIG. 13 is a partial cross-sectional view illustrating an electro-optical device according to a first application example.

FIG. 14 is a partial cross-sectional view illustrating an electro-optical device according to a second application example.

FIG. 15 is a perspective view illustrating a head-mounted display using the electro-optical device according to the embodiment.

FIG. 16 is a diagram illustrating an optical configuration of the head-mounted display.

FIG. 17 is a partially enlarged cross-sectional view illustrating a path of emitted light from an electro-optical device according to a comparative example.

### DESCRIPTION OF EMBODIMENTS

Hereinafter, an electro-optical device according to an embodiment will be described with reference to the accompanying drawings. In each drawing, dimensions and scales of each portion are appropriately different from actual ones. Further, since embodiments to be described below are preferred specific examples, various technically preferable limitations are applied, but the scope of the present disclosure is not limited to these embodiments unless it is otherwise stated in the following description that the present disclosure is limited.

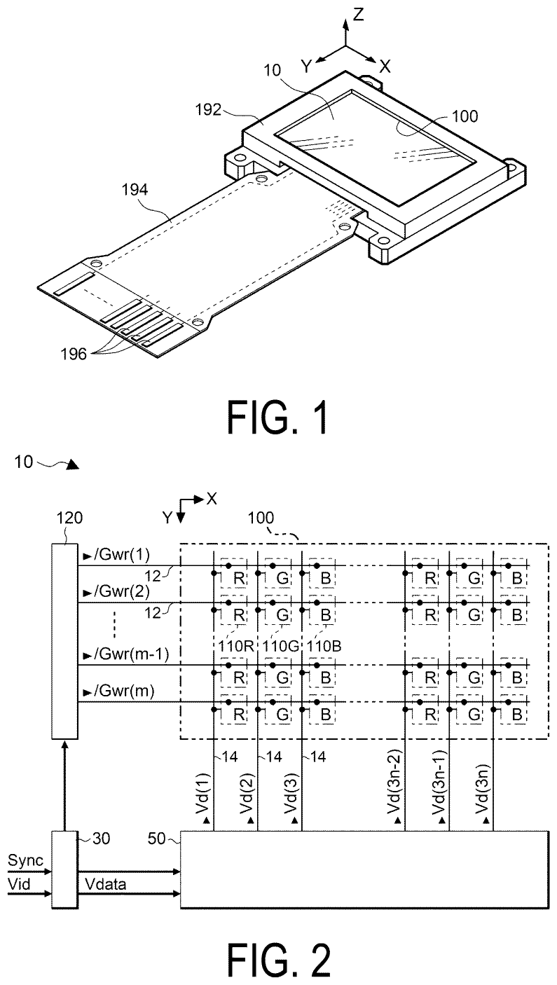

FIG. 1 is a perspective view illustrating an electro-optical device 10 according to a first embodiment, and FIG. 2 is a block diagram illustrating an electrical configuration of the electro-optical device 10.

The electro-optical device 10 is, for example, a micro display panel that displays color images in a head-mounted display or the like. The electro-optical device 10 includes, for example, a plurality of pixel portions and a drive circuit for driving the pixel portions. The pixel portions and the driving circuit are integrated on a semiconductor substrate. The semiconductor substrate is typically a silicon substrate, but may be another semiconductor substrate.

The electro-optical device 10 is accommodated in a frame-shaped case 192 that opens in the display region 100. One end of an FPC board 194 is coupled to the electro-optical device 10. FPC is an abbreviation for Flexible Printed Circuit. The other end of the FPC board 194 is provided with a number of terminals 196 for coupling to a host device ((not illustrated)). When a plurality of terminals 196 are coupled to the host device, video data, a synchronization signal, and the like are supplied from the host device to the electro-optical device 10 via the FPC board 194.

As illustrated in FIG. 2, the electro-optical device 10 includes a control circuit 30, a data signal output circuit 50, a display region 100, and a scanning line driving circuit 120.

In the display region 100, m rows of scanning lines 12 are provided along the X direction, and (3n) columns of data lines 14 are provided to be along the Y direction and to be electrically insulated from the respective scanning lines 12. m is an integer equal to or greater than 2, and n is an integer equal to or greater than 2.

To generalize and explain the scanning lines 12, an integer i of 1 or more and m or less is used. To distinguish the rows of the scanning lines 12, the rows may be referred to as first, second, third, . . . (i-1)-th, i-th, . . . , (m-1)-th, and m-th rows in order from the top in the figure.

Similarly, an integer j equal to or greater than 1 and equal to or smaller than n is used to generalize the data lines 14. To distinguish columns of the data lines 14, the columns may be referred to as first, second, third, . . . , (3j-2)-th, (3j-1)-th, (3j)-th, . . . , (3n-2)-th, (3n-1)-th, and (3n)-th columns from the left in the figure.

In the display region 100, a pixel portion 110R that emits light in a red wavelength region, a pixel portion 110G that emits light in a green wavelength region, and a pixel portion 110B that emits light in a blue wavelength region are provided in the following manner to correspond to intersections of the m-th row of scanning line 12 and the (3n)-th column of data line 14.

The pixel portion 110R is provided to correspond to an intersection of the scanning line 12 of each row and the (3j-2)-th column of data line 14. The pixel portion 110G is provided to correspond to an intersection of the scanning line 12 of each row and the (3j-1)-th column of data line 14. The pixel portion 110B is arranged to correspond to an intersection of the scanning line 12 of each row and the (3j)-th column of data line 14.

That is, in the display region 100, pixel portions 110R, 110G, and 110B are arranged in this order along the X direction. A single color is expressed by additive color mixing of three pixel portions 110R, 110G, and 110B adjacent in the X direction. Thus, the electro-optical device 10 displays an image in which color pixels are arranged in m rows and n columns.

Strictly speaking, the pixel portions 110R, 110G, and 110B should be called sub-pixel portions, but are referred to as pixel portions for convenience of description. Further, when the pixel portions 110R, 110G, and 110B are generally described without specifying the color, the pixel portions 110R, 110G, and 110B are denoted by a reference number 110.

The control circuit 30 controls each part based on the video data Vid or the synchronization signal Sync supplied from a host device (not illustrated). Specifically, the control circuit 30 generates various control signals to control the respective parts.

The video data Vid designates the gradation level of the pixel in the image to be displayed, for example, in 8 bits. The synchronization signal Sync includes a vertical synchronization signal for giving an instruction for starting vertical scanning of the video data Vid, a horizontal synchronization signal for giving an instruction for starting horizontal scanning, and a dot clock signal that indicates a timing of one pixel of the video data.

The luminance characteristics at the gradation level indicated by the video data Vid supplied from the host device do not necessarily match the luminance characteristics of the OLED included in the pixel portion 110. Thus, to make the OLED emit light at a luminance corresponding to the gradation level indicated by the video data Vid, the control circuit 30 up-converts 8 bits of the video data Vid into, for example, 10 bits and outputs it as video data Vdata. Therefore, the 10-bit video data Vdata becomes data corresponding to R, G, and B gradation levels designated by the video data Vid.

For the upconversion, a lookup table in which a correspondence relationship between 8 bits of the video data Vid that is an input and 10 bits of the video data Vdata that is an output is prestored is used.

The scanning line driving circuit 120 is a circuit for driving the pixel portions 110 arranged in m rows and 3n columns one by one under the control of the control circuit 30. Specifically, the scanning line driving circuit 120 supplies scanning signals /Gwr(1), /Gwr(2), /Gwr(3), . . . , /Gwr(m-1), and /Gwr(m) to the scanning lines 12 in the first, second, third, . . . , (m-1)-th, and m-th rows in this order. Generally, the scanning signal supplied to the scanning line 12 in the i-th row is denoted as /Gwr(i).

The data signal output circuit 50 is a circuit for outputting a data signal to the pixel portions 110 located in the row selected by the scanning line driving circuit 120 via the data line 14 under the control of the control circuit 30. The data signal is a voltage signal obtained by converting 10-bit video data Vdata into analog data. That is, the data signal output circuit 50 converts video data Vdata for one row corresponding to pixel portions 110 in the first to (3n)-th columns in the selected row into analog data, and outputs the analog data to the first to (3n)-th column of data lines 14 in this order.

Although not illustrated in the figure, a power supply circuit is provided outside the display region 100, and generates potentials Vel and Vct of a power supply for the control circuit 30, the scanning line driving circuit 120, the data signal output circuit 50, and the OLED.

In the figure, the data signals output to the first, second, third, . . . , (3n-2)-th, (3n-1)-th, and (3n)-th column of data lines 14 are denoted in order by Vd(1), Vd(2), Vd(3), . . . , Vd(3n-2), Vd(3n-1), and Vd(3n). Generally, for example, the potential of the data line 14 in the (3j-2)-th column is denoted by Vd(3j-2).

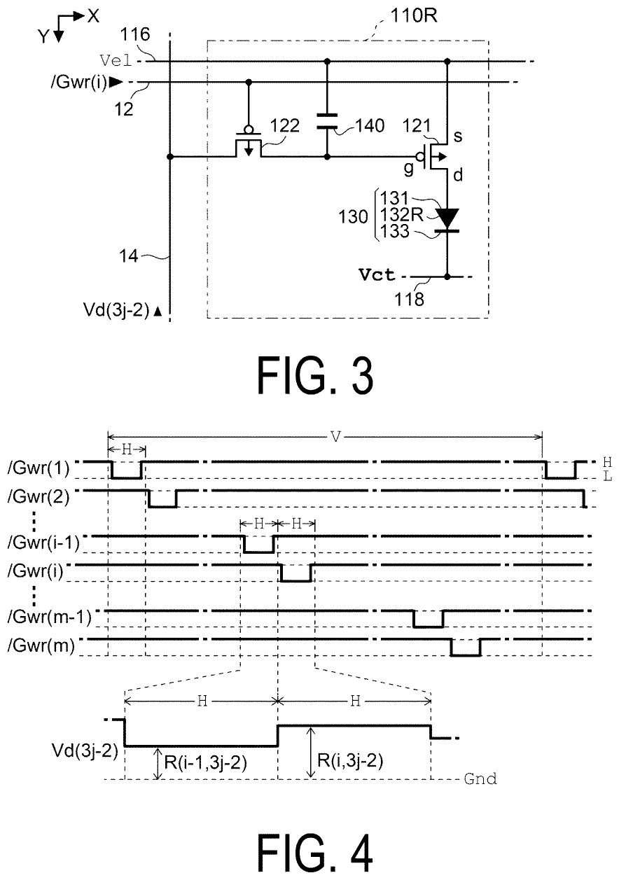

FIG. 3 is a diagram illustrating an electrical configuration of the pixel portion in the electro-optical device 10.

The pixel portions 110R, 110G, and 110B have the same configuration from an electrical perspective. Therefore, an electrical configuration of the pixel portions 110R, 110G, and 110B will be described with the pixel portion 110R corresponding to the i-th row and (3j-2)-th column as an example.

As shown in the figure, the pixel portion 110R includes P-channel MOS transistors 121 and 122, an OLED 130, and a capacitance element 140 from an electrical perspective.

In the description of the pixel portion, the phrase “electrically” is used to refer to the plurality of elements constituting the pixel portion and coupling relationship between the plurality of elements.

In the OLED 130 of the pixel portion 110R, a light-emitting layer 132R is sandwiched between a pixel electrode 131 and a common electrode 133. The light-emitting layer 132R emits light including an R wavelength range. The pixel electrode 131 functions as an anode, and the common electrode 133 functions as a cathode. In the OLED 130, when a current flows from the anode to the cathode, holes injected from the anode and electrons injected from the cathode are recombined in the light-emitting layer 132R to generate excitons, and light including the R wavelength range is generated.

In the OLED 130 of the pixel portion 110G, the light-emitting layer 132G is sandwiched between the pixel electrode 131 and the common electrode 133. The light-emitting layer 132G emits light including a G wavelength range. In the OLED 130 of the pixel portion 110B, the light-emitting layer 132B is sandwiched between the pixel electrode 131 and the common electrode 133. The light-emitting layer 132B emits light including a B wavelength range.

Each of the light-emitting layers 132R, 132G, and 132B includes at least a light-emitting functional layer that emits light of each color. The light-emitting layers 132R, 132G, and 132B may have a configuration in which one or more organic layers other than the light-emitting functional layer are sandwiched. When the light-emitting layers 132R, 132G, and 132B are described generally without specifying the color, the light-emitting layers 132R, 132G, and 132B may be denoted by the reference numeral 132.

In the transistor 121 of the pixel portion 110R in the i-th row and the (3j-2)-th column, a gate node g is coupled to the drain node of the transistor 122, a source node is coupled to the power supply line 116 for the potential Vel, and a drain node is coupled to the pixel electrode 131 which is the anode of the OLED 130.

In the transistor 122 of the pixel portion 110R in the i-th row and the (3j-2)-th column, a gate node is coupled to the scanning line 12 in the i-th row, and a source node is coupled to the data line 14 of the (3j-2)-th column. The common electrode 133 functioning as the cathode of the OLED 130 is coupled to the power supply line 118 of a potential Vct. Further, since the electro-optical device 10 is formed at a silicon substrate, a substrate potential of the transistors 121 and 122 is set to, for example, a potential equivalent to the potential Vel.

The pixel portion 110R illustrated in FIG. 3 is common to the pixel portions 110G and 110B from an electrical perspective. However, the light-emitting layer 132R is replaced with the light-emitting layer 132G in the pixel portion 110G, and is replaced with the light-emitting layer 132B in the pixel portion 110B.

The X direction is a direction in which the scanning lines 12 in the electro-optical device 10 extends, and is a horizontal direction on the display screen. The Y direction is a direction in which the data lines 14 extends, and is a vertical direction on the display screen. A two-dimensional plane defined by the X and Y directions is a substrate surface of the semiconductor substrate. The Z direction is perpendicular to the X and Y directions, and corresponds to an emission direction of light emitted from the OLED 130. The Z direction can be rephrased as the display surface side. Further, in the present description, a plan view refers to a view of the semiconductor substrate from an opposite direction to the Z direction, and a cross-sectional view refers to a view of the semiconductor substrate cut in a direction perpendicular to the substrate surface.

FIG. 4 is a timing chart for describing an operation of the electro-optical device 10.

In the electro-optical device 10, m rows of scanning lines 12 are scanned one row at a time in an order of first, second, third, . . . , (m-1))-th and m-th rows in a period of one frame (V). In detail, as shown in the figure, the scanning signals /Gwr(1), /Gwr(2), /Gwr(3), . . . , /Gwr(m-1), and /Gwr(m) are sequentially and exclusively set to an L level by the scanning line driving circuit 120 for each horizontal scanning period (H).

In the preset embodiment, periods in which the adjacent scanning signals among the scanning signals /Gwr(1) to /Gwr(m) are at the L level are separated in time. Specifically, after a scanning signal /Gwr(i-1) changes from an L level to a H level, the next scanning signal /Gwr(i) becomes at an L level after a period. This period corresponds to a horizontal blanking period.

In the present description, the period of the one frame (V) refers to a period required to display one frame of the image designated by the video data Vid. When a length of the period of the one frame (V) is the same as a vertical synchronization period, for example, when a frequency of the vertical synchronization signal included in the synchronization signal Sync is 60 Hz, the length is 16.7 milliseconds corresponding to one cycle of the vertical synchronization signal. Further, the horizontal scanning period (H) is a time interval at which the scanning signals /Gwr(1) to /Gwr(m) become at the L level in order, but for convenience in the figure, a start timing of the horizontal scanning period (H) is approximately at a center of the horizontal blanking period.

When a certain scanning signal among the scanning signals /Gwr(1) to /Gwr(m), for example, the scanning signal /Gwr(i) supplied to the scanning line 12 in the i-th row becomes an L level, the transistor 122 enters an ON state in the pixel portion 110R of the i-th row and the (3j-2)-th column. As a result, the gate node g of the transistor 121 in the pixel portion 110R is electrically coupled to the data line 14 of the (3j-2)-th column.

In the present description, an “ON state” of the transistor means that the source node and drain node of the transistor are electrically closed and enters a low impedance state. Moreover, an “off state” of the transistor means that the source node and drain node are electrically open and enters a high impedance state.

Further, in the present description, “electrically coupled” or simply “coupled” means a state in which two or more elements are directly or indirectly coupled or connected. “Electrically decoupled” or simply “decoupled” means a state in which two or more elements are not directly or indirectly coupled or connected.

In the horizontal scanning period (H) in which the scanning signal /Gwr(i) is at the L level, the data signal output circuit 50 converts the video data Vdata decomposed into R, G, and B into analog potentials Vd(1) to Vd(3n) and outputs the potentials Vd(1) to Vd(3n) as data signals to the data lines 14 in first to (3n)-th columns in order. The video data Vdata decomposed into R, G, and B is primary color components of gradation levels of the pixels in first row and first column to i-th row and (3n)-th column indicated by the video data Vid.

For example, in the (3j-2)-th column, the data signal output circuit 50 converts a R gradation level R(i,j) of the pixel in the i-th row and j-th column indicated by the video data Vid into an analog signal potential Vd(3j-2) and outputs the analog signal potential Vd(3j-2) as a data signal to the (3j-2)-th column data line 14. In the horizontal scanning period (H) when the scanning signal /Gwr(i-1) one row before the scanning signal /Gwr(i) becomes at the L level, the data signal output circuit 50 converts an R gradation level R(i-1, j) of the pixel in a (i-1)-th row and a j-th column into an analog signal potential Vd(3j-2) and outputs the analog signal potential Vd(3j-2) as a data signal to the (3j-2)-th column data line 14.

The data signal of the potential Vd(3j-2) is applied to the gate node g of the transistor 121 in the pixel portion 110R in the i-th row and the (3j-2)-th column via the data line 14 in the (3j-2)-th column, and the potential Vd(3j-2) is held in the capacitance element 140. Therefore, the transistor 121 causes a current according to a voltage between the gate node and the source node to flow through the OLED 130.

Even when the scanning signal /Gwr(i) becomes at the H level and the transistor 122 is turned off, the potential Vd(3j-2) is held by the capacitance element 140, so that a current continues to flow through the OLED 130. Therefore, in the pixel portion 110R in the i-th row and (3j-2)-th column, the OLED 130 continues to emit light at the voltage held by the capacitance element 140, that is, at a brightness according to the gradation level, until the period of the one frame (V) has elapsed, the transistor 122 is turned on again, and the potential of the data signal is applied again.

Although the pixel portion 110R in the i-th row and (3j-2)-th column has been described here, the OLEDs 130 of the pixel portions 110R, 110G, and 110B in the i-th row and the columns other than the (3j-2)-th column also emit light at a luminance indicated by the video data Vdata.

Further, the OLEDs 130 of the pixel portions 110R, 110G, and 110B in the rows other than the i-th row also emit light at the luminance indicated by the video data Vdata as the scanning signals /Gwr(1) to /Gwr(m) sequentially becomes at the L level.

Therefore, in the electro-optical device 10, the OLEDs 130 in all the pixel portions 110R, 110G, and 110B from the first row and the first column to the m-th row and the (3n)-th column emit light at the luminance indicated by the video data Vdata in the period of the one frame (V), and one frame of an image is displayed.

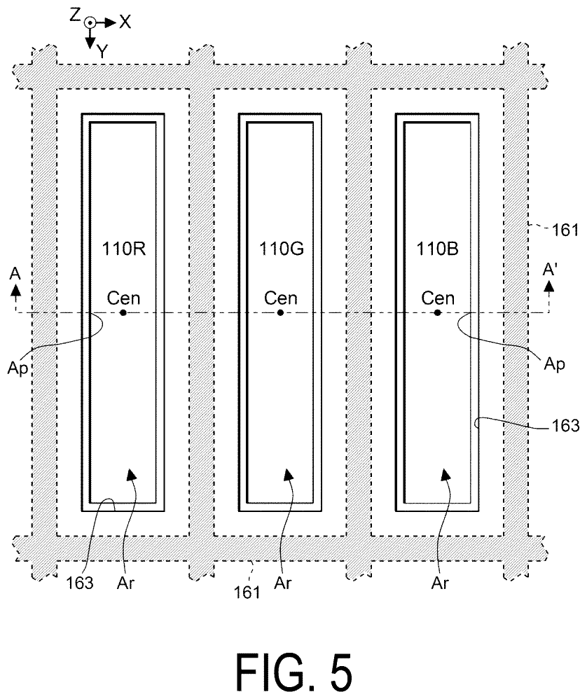

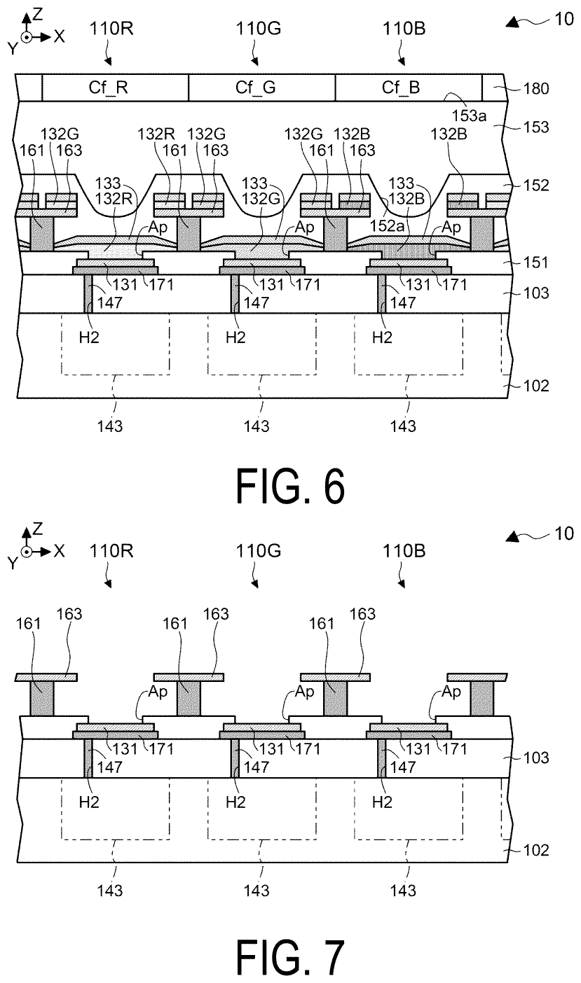

FIG. 5 is a plan view illustrating an example of disposition of the pixel portions 110R, 110G, and 110B in the electro-optical device 10, and FIG. 6 is a cross-sectional view of main parts taken along line A-A′ in FIG. 5.

As illustrated in FIG. 5 or as described above, the pixel portions 110R, 110G, and 110B are arranged side by side in the X direction repeatedly in this order in plan view.

In FIG. 6, the substrate 102 is a semiconductor substrate such as silicon. The substrate 102 is provided with a circuit layer 143. The circuit layer 143 is provided to correspond to the pixel portion 110R, 110G, or 110B, and elements such as the transistors 121 and 122, or various wirings are provided.

An insulating layer 103 is provided on the substrate 102. Contact holes H2 are provided in the insulating layer 103. The contact holes H2 are filled with a coupling member 147 such as tungsten.

A laminate of a reflective electrode 171 and a pixel electrode 131 is provided for each of the pixel portions 110R, 110G, and 110B.

Specifically, a metal wiring layer having light reflectivity such as Al, an alloy thereof, or Ag is formed at the insulating layer 103 filled with the coupling member 147. After the film formation, the metal wiring layer is in contact with the coupling member 147, and the reflective electrode 171 is provided by patterning of a rectangular shape in plan view.

A transparent conductive layer having optical transparency and conductivity, such as indium tin oxide (ITO) is formed to cover the insulating layer 103 and the reflective electrode 171. After the film formation, the pixel electrode 131 is provided by patterning such that the transparent conductive layer overlaps the reflective electrode 171 and, in plan view, is positioned inside the periphery of the reflective electrode 171.

When Al is used for the reflective electrode 171, it is preferable to adopt a configuration in which a conductive material such as TiN is provided as a barrier layer with a thickness of about several nm between the reflective electrode 171 and the pixel electrode 131 made of ITO.

Since the reflective electrode 171 comes into contact with the coupling member 147, the pixel electrode 131 is electrically coupled to the drain node of the transistor 121 included in the circuit layer 143 via the reflective electrode 171 and the coupling member 147.

A pixel separation layer 151 having transparency and an insulation property is provided to cover the insulating layer 103, the reflective electrode 171, and the pixel electrode 131. Then, an opening region Ar for exposing the pixel electrode 131 is provided in the pixel separation layer 151 by patterning. In detail, the opening region Ar has a rectangular shape that is defined by the opening end Ap as illustrated in FIG. 5 in plan view, and is provided to overlap the periphery of the pixel electrode 131 as illustrated in FIG. 6 in cross-sectional view.

The partition wall 161 and the upper portion 163 are provided after the pixel separation layer 151 is patterned.

FIG. 7 is a cross-sectional view illustrating a state in which the partition wall 161 and the upper portion 163 are provided in a manufacturing process for the electro-optical device 10.

The partition wall 161 and the upper portion 163 are provided, for example, by patterning all at once. Specifically, the partition wall 161 and the upper portion 163 are provided at boundaries between the adjacent pixel portions 110R, 110G, and 110B, as indicated by hatching in FIG. 5, in plan view.

The partition wall 161 and the upper portion 163 are formed in a grid shape in a portion extending along the X direction and a portion extending along the Y direction in plan view.

The partition wall 161 is formed of a metal wiring layer having conductivity such as aluminum. The upper portion 163 is made of a conductive metal wiring layer such as titanium, which is made of a material that has a lower etching rate than the partition wall, that is, is less susceptible to etching.

In a one-time etching, the etching of the partition wall 161 proceeds faster than the etching of the upper portion 163, so that the upper portion 163 becomes wider than the partition wall 161 in plan view, and both ends of the upper portion 163 protrude from a side surface of the partition wall 161 in cross-sectional view, forming a so-called overhang structure.

The side surface of the partition wall 161 is shown in a tapered shape in cross-sectional view as will be described later, that is, in which a width in the X direction or Y direction narrows toward the Z direction, which is the display surface side in the figure, but is not shown in the tapered shape for simplified description in FIGS. 6 and 7. Further, the partition wall 161 extends to the outside of the display region 100 and is electrically coupled to an output terminal of the power supply circuit. Therefore, the partition wall 161 is maintained at the potential Vct generated by the power supply circuit. Further, the upper portion 163 is made of a conductive metal wiring layer, but may be made of a material having an insulative property.

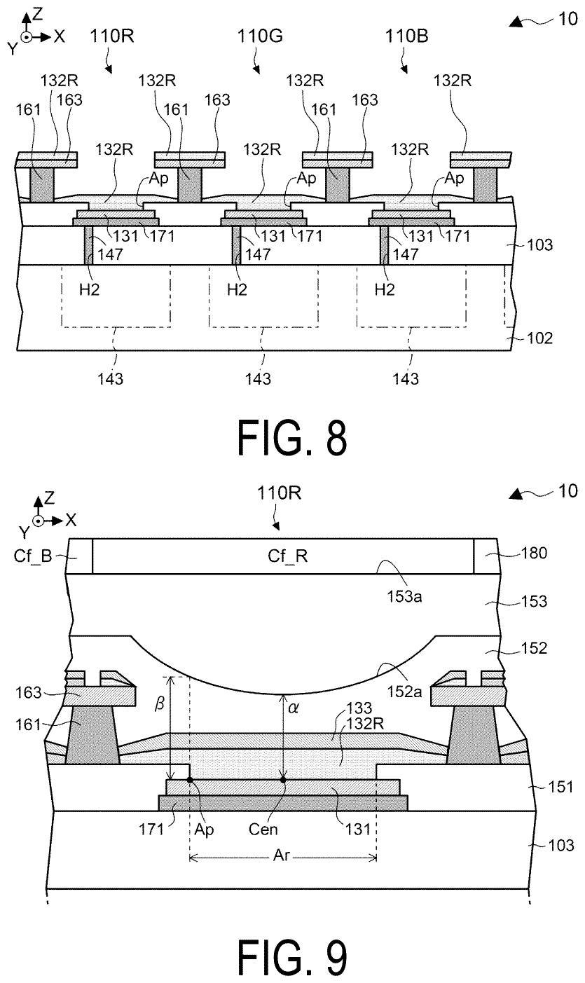

FIG. 8 is a cross-sectional view illustrating a state immediately after the light-emitting layer 132R is formed in a manufacturing process for the electro-optical device 10.

The light-emitting layer 132R is formed through deposition using an upper direction in the figure as a deposition source. Therefore, the light-emitting layer 132R is formed to cover the opening region Ar of the pixel separation layer 151 in the pixel portion 110R, and is also formed at an upper surface of the upper portion 163.

In other words, the light-emitting layer 132R is formed to overlap the pixel electrode 131 in the pixel portion 110R, using the already-provided upper portion 163 as a mask. Therefore, since the light-emitting layer 132R is formed by self-alignment, not by photolithography, an exposure process using an expensive fine metal mask is not required.

The light-emitting layer 132R is also provided in the pixel portions 110G and 110B for different colors at this stage, but is removed by subsequent etching.

After the light-emitting layer 132R is formed, the common electrode 133 is provided by forming a conductive layer having transparency, reflectivity and conductivity. The common electrode 133 comes into contact with a side wall of the partition wall 161. Therefore, the common electrode 133 is maintained at the potential Vct via the partition wall 161. Thereafter, a sealing layer 152 is provided to cover the common electrode 133, the partition wall 161, and the upper portion 163.

At this stage, the light-emitting layer 132R, the common electrode 133, and the sealing layer 152 are provided on the pixel electrode 131 in an overlapping manner in the pixel portions 110G and 110B.

In order to provide the corresponding light-emitting layer 132G of correct color in the pixel portion 110G, the sealing layer 152 in the pixel portion 110R is first covered with a photoresist for protection. Thereafter, the sealing layer 152, the common electrode 133, and the light-emitting layer 132R in the pixel portions 110G and 110B are removed by etching. Accordingly, the pixel electrode 131 is exposed in the pixel portions 110G and 110B.

Thereafter, the photoresist in the pixel portion 110R is removed, and, similar to the pixel portion 110R, the light-emitting layer 132G of G is formed in self-alignment in the pixel portion 110G using the upper portion 163 as a mask, and the common electrode 133 and the sealing layer 152 are provided in this order.

At this stage, in the pixel portion 110R, the light-emitting layer 132G, the common electrode 133, and the sealing layer 152 are provided to overlap the light-emitting layer 132R, the common electrode 133, and the sealing layer 152. Further, in the pixel portion 110B, the light-emitting layer 132G, the common electrode 133, and the sealing layer 152 are provided on the pixel electrode 131 in an overlapping manner.

Therefore, first, in the pixel portion 110G, the sealing layer 152 is covered with photoresist for protection. Thereafter, the sealing layer 152, the common electrode 133, and the light-emitting layer 132G that are provided to overlap in the pixel portion 110R are removed by etching, and the sealing layer 152, the common electrode 133, and the light-emitting layer 132G in the pixel portion 110B are also removed by the same etching. Accordingly, the pixel electrode 131 is exposed in the pixel portion 110B.

Thereafter, the photoresist of the pixel portion 110G is removed, and in the pixel portion 110B, the B light-emitting layer 132B is formed by self-alignment using the upper portion 163 as a mask, and the common electrode 133 and the sealing layer 152 are provided in order, similar to the pixel portion 110R.

At this stage, in the pixel portion 110R, the light-emitting layer 132B, the common electrode 133, and the sealing layer 152 are provided again to overlap the light-emitting layer 132R, the common electrode 133, and the sealing layer 152. In the pixel portion 110G, the light-emitting layer 132B, the common electrode 133, and the sealing layer 152 are provided to overlap the light-emitting layer 132G, the common electrode 133, and the sealing layer 152.

Therefore, in the pixel portion 110B, the sealing layer 152 is covered with photoresist for protection. Thereafter, the sealing layer 152, the common electrode 133, and the light-emitting layer 132B that are provided in an overlapping manner in the pixel portion 110R, and the sealing layer 152, the common electrode 133, and the light-emitting layer 132B in the pixel portion 110G are each removed by etching.

Accordingly, in the pixel portion 110R, the sealing layer 152 is provided to cover the pixel electrode 131, the light-emitting layer 132R, and the common electrode 133. Similarly, in the pixel portion 110G, the sealing layer 152 is provided to cover the pixel electrode 131, the light-emitting layer 132G, and the common electrode 133, and in the pixel portion 110B, the sealing layer 152 is provided to cover the pixel electrode 131, the light-emitting layer 132B, and the common electrode 133.

The sealing layer 152 is a layer for preventing moisture from penetrating the light-emitting layers 132R, 132G, and 132B, and includes a single film or a laminated film of an inorganic material such as SiN, SiON, or Al2O3. For formation of the sealing layer 152, sputtering, CVD, AVD, or the like is appropriately used.

In a state where the light-emitting layer 132R and the common electrode 133 are provided in the pixel portion 110R, the partition wall 161 and the upper portion 163 are located higher than the common electrode 133 in cross-sectional view, that is, on the display surface side in the Z direction. When the sealing layer 152 is provided to cover the partition wall 161, the upper portion 163, and the common electrode 133 in such a positional relationship, the upper surface 152a of the sealing layer 152 has a concave surface as will be described next in cross-sectional view.

FIG. 9 is a partial enlarged cross-sectional view illustrating a concave surface in the electro-optical device 10. In cross-sectional view, the partition wall 161 and the upper portion 163 are located higher than the common electrode 133, so that the upper surface 152a of the sealing layer 152 is concave in a region overlapping the opening region Ar in plan view. In detail, as illustrated in FIG. 5 or 9, when a diagonal center of the opening region Ar is Cen, a distance β from the opening end Ap to the upper surface 152a of the sealing layer 152 in the pixel electrode 131 is longer than a distance α from the diagonal center Cen to the upper surface 152a of the sealing layer 152.

A planarization layer 153 is provided to cover the sealing layer 152 having such a concave surface. The planarization layer 153 is a layer for planarizing the sealing layer 152, and is obtained by forming an inorganic material having a refractive index larger than that of the sealing layer 152. For the planarization layer 153, titanium oxide, niobium oxide, hafnium oxide, tantalum oxide, zirconium oxide, or the like may be used. The planarization layer 153 is formed by appropriately using sputtering, CVD, AVD, deposition, or the like.

An upper surface 153a of the planarization layer 153 is planarized by, for example, CMP. Although the pixel portion 110R has been described as an example here, the upper surface 152a of the sealing layer 152 in the pixel portions 110G and 110B is similarly concave in the opening region Ar.

A colored layer 180 is provided to cover the planarization layer 153. The colored layer 180 collectively refers to Cf_R provided in the pixel portion 110R, Cf_G provided in the pixel portion 110G, and Cf_B provided in the pixel portion 110B. In plan view, the colored layer Cf_R covers the opening region Ar of the pixel portion 110R, the colored layer Cf_G covers the opening region Ar of the pixel portion 110G, and the colored layer Cf_B covers the opening region Ar of the pixel portion 110B.

The colored layers Cf_R, Cf_G, and Cf_B are provided by patterning a photosensitive resin containing a pigment that selectively transmits respective colors of light using a photolithography technology, and have a function of transmitting respective colors of light.

Here, red colored light transmitted by the colored layer Cf_R specifically has a light color in a wavelength range from 580 nm to 700 nm. Green colored light transmitted by the colored layer Cf_G specifically has a light color in a wavelength range from 500 nm to 580 nm. Blue colored light transmitted by the colored layer Cf_B specifically has a light color in a wavelength range from 400 nm to 500 nm.

In the present embodiment, the light-emitting layer 132R emits red light, and the red light emitted from the light-emitting layer 132R passes through the colored layer Cf_R and is visible to the user. The green light emitted from the light-emitting layer 132G passes through the colored layer Cf_G and is visible to the user, and similarly, the blue light emitted from the light-emitting layer 132B passes through the colored layer Cf_B and is visible to the user. This makes it possible to increase the purity of the color visible to the user compared to a configuration in which the white light emitted from the light-emitting layer is colored by a colored layer, or a configuration in which the colored layer 180 is not included and the light emitted from the light-emitting layers 132R, 132G, and 132B is directly visible.

When the colored layers Cf_R, Cf_G, and Cf_B are provided to cover the planarization layer 153, the configuration illustrated in FIG. 6 is obtained.

In FIG. 6, the light-emitting layers 132R, 132G, and 132B and the same conductive layer as the common electrode 133 are overlapped on the upper surface of the upper portion 163, but are separated near boundaries of the pixel portions 110R, 110G, and 100B. This space is caused by etching for protection of the photoresist.

In order to describe the advantages of the electro-optical device 10 according to the present embodiment, a comparative example according to the present embodiment will be described.

FIG. 17 is a diagram illustrating a light emission path in an electro-optical device according to a comparative example, with the red pixel portion 110R as an example.

In the comparative example, the upper surface 152a of the sealing layer 152 is a concave surface in cross-sectional view in the opening region Ar, as in the embodiment. However, in the comparative example, a planarization layer 159 is made of an organic material such as epoxy resin, rather than an inorganic material as in the embodiment. Since a photosensitive resin contained in the colored layer 180 is an organic material, it is preferable that the sealing layer 152 is also made of the same organic material when adhesion to the colored layer 180 is considered.

However, the epoxy resin in the planarization layer 159 generally has a refractive index of about 1.5 to 1.6. On the other hand, when the sealing layer 152 is made of SiN, the refractive index thereof is about 1.9 to 2.0. Therefore, in the comparative example, since the refractive index of the planarization layer 159 is lower than that of the sealing layer 152, the light emitted from the light-emitting layer 132 is diffused by the concave surface of the sealing layer 152, and part of the light penetrates into the colored layers other than the colored layer Cf_R.

In the light emitted from the light-emitting layer 132R of the pixel portion 110R, the light that has penetrated into the colored layers other than the colored layer Cf_R can be prevented from being visible to the user by a light-shielding layer (not illustrated) or the like, but the efficiency of use of the red light is reduced. Therefore, when the luminance of the red color light is increased, a higher power is required, which adversely affects the life of the light-emitting layer 132R.

Although the red pixel portion 110R has been described here, the same applies to the green pixel portion 110G and the blue pixel portion 110B.

Further, in an electro-optical device in which the pixel portions 110R, 110G, and 110B are relatively large in size, specifically, in a direct-view display device applied to a smartphone or the like, the upper surface 152a of the sealing layer 152 is substantially flat in the opening region. Therefore, in a direct-view display device, since the emitted light does not refract at an interface between the sealing layer 152 and the planarization layer 153 and travels substantially straight, the problem of reduced light use efficiency does not occur. In other words, the problem of reduced light use efficiency due to refraction of the emitted light at the interface between the sealing layer 152 and the planarization layer 153 occurs in a micro display panel with an array pitch of pixel portions of about several μm.

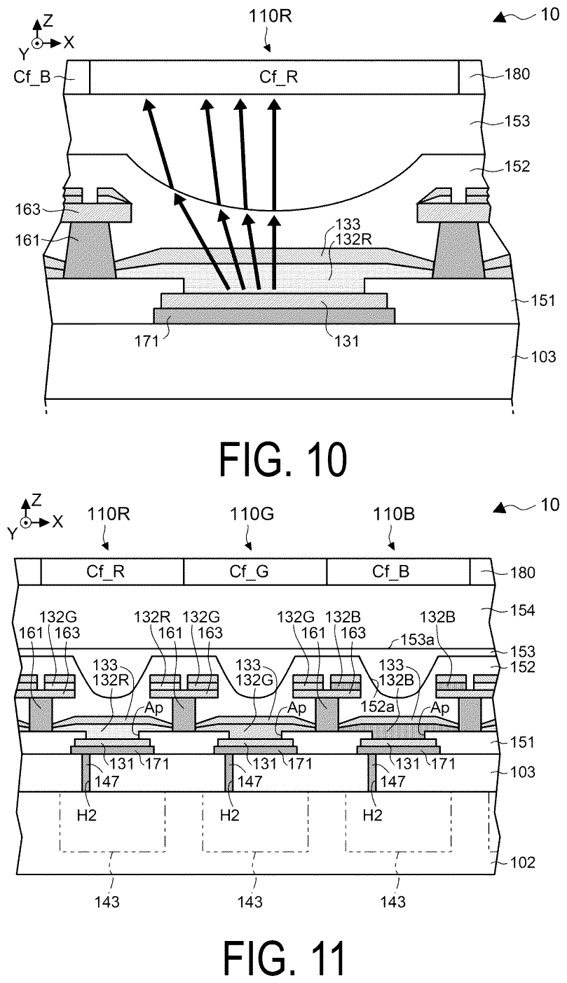

FIG. 10 is a diagram illustrating a light emission path in the electro-optical device 10 according to the first embodiment, with the red pixel portion 110R as an example.

In the first embodiment, the planarization layer 153 is made of an inorganic material, not an organic material as in the comparative example. Further, an inorganic material of the planarization layer 153 is a material with a higher refractive index than that of the sealing layer 152, such as a Ti oxide with a refractive index of about 2.3 to 2.5. Therefore, in the first embodiment, since the light emitted from the light-emitting layer 132 is collected by the concave surface of the sealing layer 152, the proportion of red light passing through the colored layer Cf_R is greater than in the comparative example. Therefore, according to the present embodiment, the efficiency of use of red light is higher than in the comparative example, so that a high-luminance display can be achieved in a state where power consumption is curbed.

Further, in the first embodiment, the partition wall 161 and the upper portion 163 are used when the light-emitting layers 132R, 132G, and 132B are formed in a self-aligned manner, and are also used as wiring for supplying the potential Vct to the common electrode 133. The concave surface on the upper surface 152a of the sealing layer 152 is formed by using the fact that the common electrode 133 is relatively lower than the partition wall 161 and the upper portion 163.

That is, in the first embodiment, the partition wall 161 and the upper portion 163 are used for formation of the light-emitting layers 132R, 132G, and 132B, wiring to the common electrode 133, and forming the concave surface on the upper surface 152a of the sealing layer 152. Therefore, in the first embodiment, the partition wall 161 and the upper portion 163 are effectively utilized.

In the electro-optical device 10 according to the first embodiment, the colored layer 180 is provided on the planarization layer 153 made of an inorganic material, so that there is concern that the adhesion of the colored layer 180 is inferior to that of the comparative example. Therefore, a second embodiment that eliminates such concern will be described.

FIG. 11 is a cross-sectional view of main portions of the electro-optical device 10 according to the second embodiment, cut as in FIG. 6. As illustrated in this figure, in the second embodiment, the planarization layer 154 is provided between the planarization layer 153 and the colored layer 180. That is, in the second embodiment, two planarization layers 153 and 154 are provided between the sealing layer 152 and the colored layer 180.

An interface between the planarization layers 153 and 154 is approximately parallel to the substrate surface. That is, a distance from the center Cen of the opening region Ar at the interface is approximately the same as a distance from the opening end Ap of the opening region Ar.

In the second embodiment, the planarization layer 153 is the same as in the first embodiment, but the planarization layer 154 is made of an organic material such as epoxy resin.

When the sealing layer 152 is SiN, the refractive index thereof is about 1.9 to 2.0, when the planarization layer 153 is Ti oxide, the refractive index thereof is about 2.3 to 2.5, and when the planarization layer 154 is epoxy Ti oxide, the refractive index thereof is about 1.5 to 1.6.

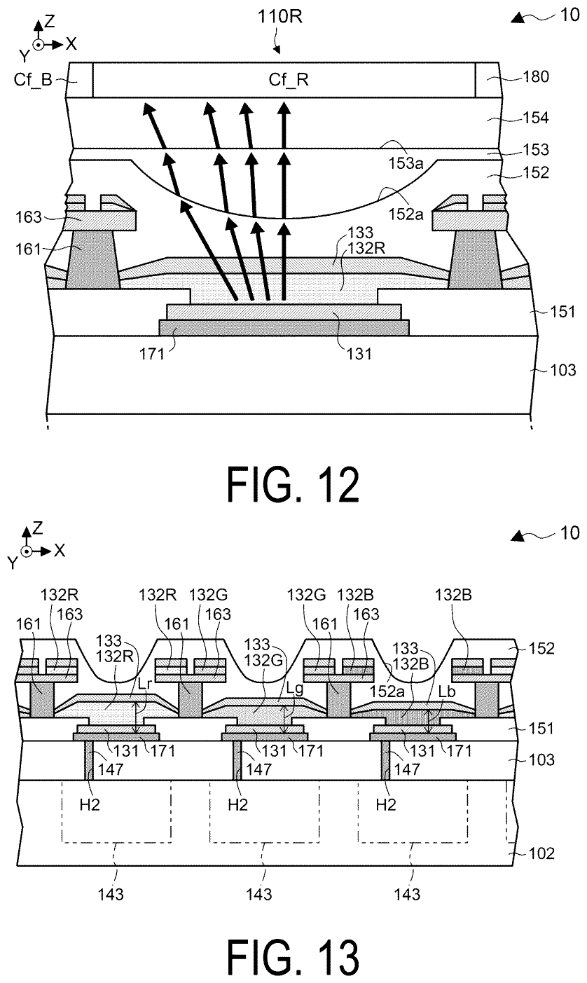

FIG. 12 is a diagram illustrating a light emission path in the electro-optical device 10 according to the second embodiment, with the red pixel portion 110R as an example.

In the second embodiment, the light emitted from the light-emitting layer 132 is collected by the concave surface of the sealing layer 152, as in the first embodiment. In the second embodiment, since a refractive index of the planarization layer 154 made of an organic material is lower than that of the planarization layer 153 made of an inorganic material, the light is diffused due to refraction at the interface between the planarization layers 153 and 154. Accordingly, in the second embodiment, the efficiency of use of the red light is lower than in the first embodiment, but since the light has been collected by the concave surface, the efficiency of use of red light is higher than in the comparative example.

Although the red pixel portion 110R has been described here, the same applies to the green pixel portion 110G and the blue pixel portion 110B, and the efficiency of use of the green and blue light is higher than in the comparative example.

In the second embodiment, the colored layer 180 is provided on the planarization layer 154 made of an organic material, so that the concern that the adhesion of the colored layer 180 is inferior to that of the comparative example can be eliminated.

The first and second embodiments (hereinafter referred to as “embodiment or the like”) described above can be modified or applied in various ways as follows.

FIG. 13 is a partial cross-sectional view illustrating main portions of an electro-optical device 10 according to a first application example.

In the first application example, the pixel portions 110R, 110G, and 100B are provided with an optical resonance structure according to the color. The optical resonance structure refers to a structure in which optical distances Lr, Lg, and Lb are set to distances corresponding to wavelengths of the respective colors when an optical distance between a reflective surface of the common electrode 133 and a reflective surface of the reflective electrode is Lr for the pixel portion 110R, Lg for the pixel portion 110G, and Lb for the pixel portion 110B. Further, for setting the optical distances Lr, Lg, and Lb to distances corresponding to the wavelengths of the respective colors, specifically, the following measures can be considered. That is, it is conceivable that,
as a first measure, film thicknesses of the light-emitting layers 132R, 132G, and 132B are made different for each color,
as a second measure, a film thickness of the transparent pixel electrode 131 is made different for each color, and
as a third measure, a sum of the film thickness of the pixel electrode 131 and a film thickness of the light-emitting layer 132R, 132G, or 132B is made different for each color. The first application example is the first of these measures.

The optical distances Lr, Lg, and Lb have a relationship of Lr>Lg>Lb.

In the optical resonance structure, light emitted from the light-emitting layer 132R, 132G, or 132B resonates due to reflection between the reflective electrode 171 and the common electrode 133, and is emitted at a resonance wavelength that has been set to correspond to the color R, G, or B.

Therefore, in the first application example with the optical resonance structure, light having a wavelength corresponding to a color is enhanced and emitted, so that a spectrum is sharpened and intensified, enabling an improvement in both color purity and brightness.

The light-emitting layer 132R, 132G, or 132B has a laminated structure of a hole injection layer, a hole transport layer, a light-emitting functional layer, an electron blocking layer, an electron transport layer, and an electron injection layer, which are not actually shown in the figure. Therefore, it is possible to make a film thickness of the light-emitting layer 132R, 132G, or 132B different for each color by adjusting the thicknesses of the layers for each color.

Strictly speaking, the optical distance is a value obtained by multiplying a distance between the reflective electrode 171 and the common electrode 133 by a refractive index of the pixel electrode 131 and the light-emitting layer, which are media between the reflective electrode 171 and the common electrode 133, but is simply shown as a physical distance in the figure.

Further, in the first application example, the transparent pixel electrode 131 can be omitted. When the pixel electrode 131 is omitted, the optical distances Lr, Lg, and Lb may be set to distances associated with the wavelengths of the respective colors by using the first measure.

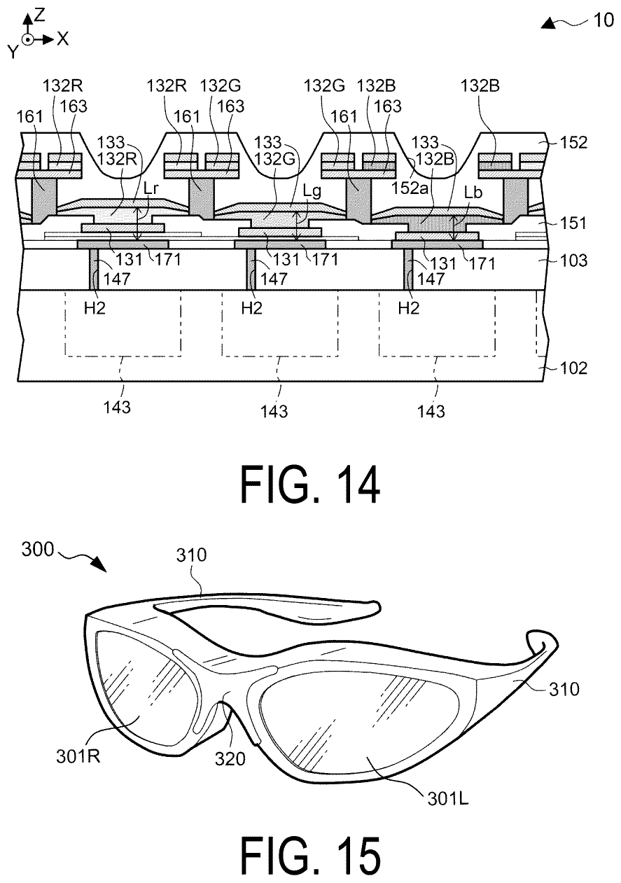

FIG. 14 is a partial cross-sectional view illustrating main portions of an electro-optical device 10 according to a second application example.

The second application example is common to the first application example in that the pixel portions 110R, 110G, and 100B have optical resonance structures according to the colors. However, the second application example differs from the first application example in that the optical distances Lr, Lg, and Lb are adjusted by a film thickness of an insulating layer provided between the pixel electrode 131 and the reflective electrode 171.

FIG. 14 illustrates an example in which the insulating layer between the pixel electrode 131 and the reflective electrode 171 is not provided in the pixel portion 110B, is one layer in the pixel portion 110G, and includes two layers obtained by adding another insulating layer to the insulating layer, that is the one layer provided in the pixel portion 110G, in the pixel portion 110R.

Since an electric field becomes weaker when the thickness of the light-emitting layer 132 increases, a higher voltage needs to be applied to obtain the same luminance, but in the second application example, the optical distance can be set to Lr>Lg>Lb in a state where the thicknesses of the light-emitting layers 132R, 132G, and 132B are uniform. Therefore, in the second application example, it is not necessary to drive the R light-emitting layer 132R having the longest optical distance with a high voltage in order to increase the color purity and the luminance.

In the first application example illustrated in FIG. 13 and the second application example illustrated in FIG. 14, elements after the planarization layer 153 are not illustrated. In the first and second application examples, the planarization layer 153 may be provided as a single layer between the sealing layer 152 and the colored layer 180 as in the first embodiment, or may be provided as multiple layers such as the planarization layers 153 and 154 as in the second embodiment.

In the embodiment or the like, an opening shape of the opening region Ar in the pixel portions 110R, 110G, and 110B is a rectangular shape, but is not limited thereto. For example, the opening shape may be a polygon such as a hexagon or may be a circle, an ellipse, or the like. Further, an opening area of the opening region Ar may not be uniform in the pixel portions 110R, 110G, and 110B, but may be different for each color. For example, B>G>R for the opening area of the opening region Ar.

The pixel portions 110R, 110G, and 110B may be aligned in the X direction or may be aligned in the Y direction. Further, the pixel portions 110R and 110B may be arranged in the same columns, and the pixel portion 110G may be arranged in a column adjacent to the column of the pixel portions 110R and 110B.

Further, in the description of the embodiment or the like, the light-emitting layers 132R, 132G, and 132B are formed in this order, but an order of formation is not limited thereto.

In the present description, the pixel electrode 131 is an example of a “first electrode”, the common electrode 133 is an example of a “second electrode”, and the OLED 130 is an example of a “light-emitting element”. The pixel separation layer 151 is an example of a “first insulating layer”, the sealing layer 152 is an example of a “second insulating layer”, the planarization layer 153 is an example of a “third insulating layer”, and the planarization layer 154 is an example of a “fourth insulating layer”.

Next, an electronic apparatus to which the electro-optical device 10 according to the embodiment is applied will be described. The electro-optical device 10 is suitable for application of a small pixel size and high definition display. Consequently, a head-mounted display will be described as an example of the electronic apparatus.

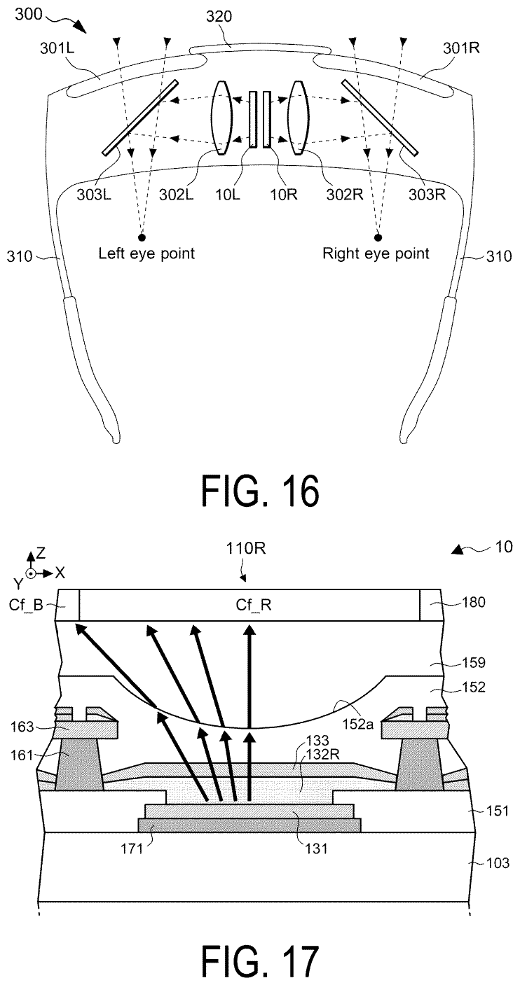

FIG. 15 is a diagram illustrating an appearance of a head-mounted display, and FIG. 16 is a diagram illustrating an optical configuration thereof.

First, as illustrated in FIG. 15, the head-mounted display 300 includes temples 310, a bridge 320, and lenses 301L and 301R in appearance, similar to ordinary eyeglasses. Further, the head-mounted display 300 is provided with an electro-optical device 10L for a left eye and an electro-optical device 10R for a right eye near the bridge 320 and behind the lenses 301L and 301R (below in the figure), as illustrated in FIG. 16.

An image display surface of the electro-optical device 10L is disposed to the left in FIG. 16. Accordingly, an image displayed by the electro-optical device 10L is emitted in a 9 o′clock direction in the figure via the optical lens 302L. A half mirror 303L reflects an image displayed by the electro-optical device 10L in the 6 o′clock direction, and transmits light incident from a 12 o′clock direction. An image display surface of the electro-optical device 10R is disposed to the right opposite to the electro-optical device 10L. Accordingly, an image displayed by the electro-optical device 10R is emitted in a 3 o′clock direction in the figure through an optical lens 302R. A half mirror 303R reflects an image displayed by the electro-optical device 10R in the 6 o′clock direction, and transmits light incident from the 12 o′clock direction.

In this configuration, a wearer of the head-mounted display 300 can observe images displayed by the electro-optical devices 10L and 10R in a see-through state, overlaid with the view of the outside.

Furthermore, in the head-mounted display 300, an image for the left eye is displayed by the electro-optical device 10L, and an image for the right eye is displayed by the electro-optical device 10R in the images for both eyes involving parallax, so that it enables the wearer to sense the displayed image as having depth or stereoscopic effect.

An electronic apparatus including the electro-optical device 10 can also be applied to an electronic viewfinder in a video camera, an interchangeable-lens digital camera, or the like, a display unit of a smart watch or a wearable device, a light bulb of a projection projector, and the like, in addition to the head-mounted display 300.

From the above illustrated forms, for example, the following aspects can be ascertained. Hereinafter, for ease of understanding of each aspect, the reference signs in the drawings are conveniently written in parentheses, but this is not intended to limit the aspects to those shown.

An electro-optical device (10) according to aspect 1 includes a light-emitting element (130) including a first electrode (131), a second electrode (133), and a light-emitting layer (132) provided between the first electrode (131) and the second electrode (133), a partition wall (161) configured to surround the light-emitting element (130) in plan view, a first insulating layer (151) configured to cover the periphery of the first electrode (131) and having an opening region (Ar) overlapping the first electrode (131) in plan view, and a second insulating layer (152) having an insulating property and transparency and configured to cover the light-emitting element (130) and the partition wall (161), and a third insulating layer (153) having an insulating property and transparency, configured to cover the second insulating layer (152), and having a higher refractive index than the second insulating layer (152). In the opening region (Ar), the first electrode (131) and the light emitting layer (132) are in contact with each other, and a surface of the second insulating layer (152) in the opening region (Ar) facing the third insulating layer (153) is a concave surface in plan view.

According to the electro-optical device of aspect 1, since a refractive index of the third insulating layer covering the second insulating layer is higher than that of the second insulating layer, and a surface of the second insulating layer facing the third insulating layer is a concave surface, the light emitted from the light emitting layer is collected. Therefore, in an electro-optical device with a narrow opening region, the efficiency of use of the light emitted from the light emitting layer can be increased.

In the electro-optical device (10) according to another specific aspect 2 of aspect 1, the third insulating layer (153) is made of an inorganic material.

In the electro-optical device (10) according to another specific aspect 3 of aspect 1, a colored layer (180) is provided on the third insulating layer (153) on the side opposite the second insulating layer (152).

In the electro-optical device (10) according to specific aspect 4 of aspect 3, a fourth insulating layer (154) having an insulating property and transparency is provided between the third insulating layer (153) and the colored layer (180).

In the electro-optical device (10) according to specific aspect 5 of aspect 4, the fourth insulating layer (154) is made of an organic material.

In the electro-optical device (10) according to another specific aspect 6 of aspect 1, a distance (β) between the first electrode and the second insulating layer (152) at an opening end (Ap) of the opening region (Ar) is larger than a distance (α) between the first electrode and the second insulating layer (152) at a center (Cen) of the opening region (Ar) in cross-sectional view.

The electro-optical device (10) according to another specific aspect 7 of aspect 1 includes an upper portion (163) provided to protrude from the partition wall (161) in cross-sectional view on the upper surface of the partition wall (161).

The electronic apparatus (300) according to aspect 8 includes the electro-optical device (10) according to any one of aspects 1 to 7.

What is claimed is:

1. An electro-optical device comprising:
a light-emitting element including a first electrode, a second electrode, and a light-emitting layer provided between the first electrode and the second electrode;
a partition wall configured to surround the light-emitting element in plan view;
a first insulating layer configured to cover the periphery of the first electrode and having an opening region overlapping the first electrode in plan view;
a second insulating layer having an insulating property and transparency and configured to cover the light-emitting element and the partition wall; and
a third insulating layer having an insulating property and transparency, configured to cover the second insulating layer, and having a higher refractive index than the second insulating layer, wherein
the first electrode and the light-emitting layer are in contact with each other in the opening region, and
a surface of the second insulating layer in the opening region facing the third insulating layer is a concave surface in plan view.

2. The electro-optical device according to claim 1, wherein
the third insulating layer is made of an inorganic material.

3. The electro-optical device according to claim 1, wherein
a colored layer is provided on the third insulating layer on the opposite side to the second insulating layer.

4. The electro-optical device according to claim 3, wherein
a fourth insulating layer having an insulating property and transparency is provided between the third insulating layer and the colored layer.

5. The electro-optical device according to claim 4, wherein
the fourth insulating layer is made of an organic material.

6. The electro-optical device according to claim 1, wherein
a distance between the first electrode and the second insulating layer at an opening end of the opening region is larger than a distance between the first electrode and the second insulating layer at a center of the opening region in cross-sectional view.

7. The electro-optical device according to claim 1, comprising:
an upper portion provided to protrude from the partition wall in cross-sectional view on the upper surface of the partition wall.

8. An electronic apparatus comprising the electro-optical device according to claim 1.
